(19) United States
(12) Patent Application Publication
(10) Pub. No.: US 2023/0004042 A1
(43) Pub. Date: Jan. 5, 2023

(54) A HEAT INSULATION BARRIER AND A LIQUID CRYSTAL DISPLAY COMPRISING IT

(71) Applicant: BILKENT UNIVERSITESI (UNAM) ULUSAL NANOTEKNOLOJI ARASTIRMA MERKEZI, Ankara (TR)

(72) Inventors: Hilmi Volkan DEMIR, Ankara (TR); Emre UNAL, Ankara (TR)

(73) Assignee: BILKENT UNIVERSITESI (UNAM) ULUSAL NANOTEKNOLOJI ARASTIRMA MERKEZI, Ankara (TR)

(21) Appl. No.: 17/784,432

(22) PCT Filed: Dec. 11, 2020
(86) PCT No.: PCT/TR2020/051272

§ 371 Date: Jun. 10, 2022

(30) Foreign Application Priority Data
Dec. 12, 2019 (TR) 2019/19978

(51) Int. Cl. G02F 1/1333

(52) U.S. Cl. CPC G02F 1/133382; G02F 1/133345

(57) ABSTRACT

The present invention relates to a barrier (1) which provides heat insulation by being contacted with displays of liquid crystal display (LCD) type.

### TECHNICAL FIELD

The present invention relates to a barrier which provides heat insulation by being contacted with displays of liquid crystal display (LCD) type.

### BACKGROUND OF THE INVENTION

In display technologies, displays can create image and operate in the range of −40° C. and 85 ° C. due to temperature-dependent properties of the liquid crystal material used. Therefore, displays used in outdoor areas must he designed by performing heat management in order that these can operate at higher and/or lower temperatures. However, surface width and proximity to the external environment complicate this design and worsen other elements such as image quality, brightness. Therefore, it is required to perform heat management without distorting the existing properties of displays.

The Chinese patent document No. CN105318636, an application in the state of the art, discloses a liquid crystal display freezer door. The freezer door comprises an aluminum alloy door frame, a hunt panel glass, a back panel glass, a transparent liquid ciystal display, a reflective film, and a light source. The from panel glass is arran,ged at the front end of the aluminum alloy door frame and the back panel glass is arranged at the back end thereof. A hollow and sealed space is formed between the front panel glass and the back panel glass. The transparent liquid crystal display is placed in the gap between these glasses. The display in the freezer door having this structure provides a good heat protection, and mprovement in transparency and image quality of the display.

The Chinese patent document No. CN 205548146, an application in the state of the art, discloses a cupboard door body comprising a hollow glass. The door body comprises a transparent glass layer from outside to inside, a transparent display layer and a dimming glass layer. The transparent glass layer is always kept transparent and it is used to see the inner layer structure and protect the inner layer structure. The transparent glass layer is placed between the transparent glass layer and the dimming glass layer, and it does not make contact with both glass layers. Due to the small gap of the hollow structure, power consumption and change in internal temperature of the display cupboard are reduced.

### SUMMARY OF THE INVENTION

An objective of the present invention is to realize a heat insulation barrier and a liquid crystal display comprising it which enable to create image at higher and lower temperatures in comparison to existing displays without distorting image quality and brightness of displays.

Another objective of the present invention is to realize a heat insulation barrier and a liquid crystal display comprising it which prevent convection of heat reaching the display by external factors, and provide heat insulation

### DETAILED DESCRIPTION OF THE INVENTION

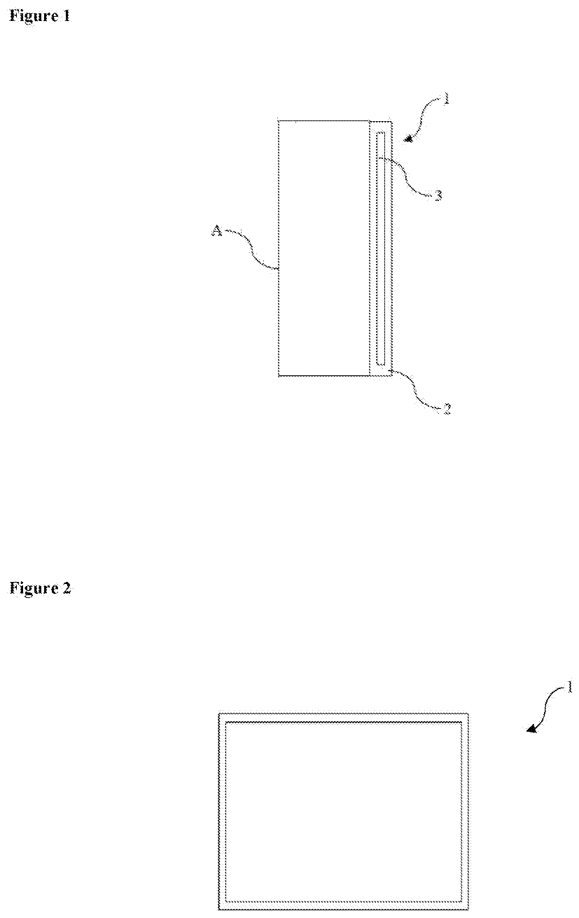

“A Heat Insulation Barrier and A Liquid Crystal Display Comprising It” realized to fulfil the objectives of the present invention is shown in the figures attached, in which:
FIG. 1 is a sectional view of the inventive heat insulation barrier wherein it is fixed to liquid crystal displays.
FIG. 2 is a front view of the inventive heat insulation barrier wherein it is fixed to liquid crystal displays.

The components illustrated in the figure are individually numbered, where the numbers refer to the following:

1. Heat insulation barrier

2. Plate

3. Groove

### A: Display

The inventive heat insulation barrier (1) for providing heat insulation in liquid crystal displays (A) with at least one font surface and one back surface comprises:
at least one plate (2) which has two opposite planar surfaces that can be fixed to the front and/or the back surface of the displays (A); and
at least one groove (3) which is located between two surfaces of the plate (2), and created such that interconnection of the surfaces will not completely break off.

The plate (2) included in the inventive heat insulation barrier (1) creates a layer on the surface of the displays (A) of liquid crystal display type, by being fixed to the front surface and/or the back surface of the displays (A) such that no gap will remain between it and the display surface. The plate (2) is fixed onto the related surface of the display (A) by means of transparent polymer-based materials curing and hardening by heat or UV light. In a preferred embodiment, the plate (2) is made of a thin transparent glass material and it is configured such that it will have a maximum thickness of 1 mm and due to the fact that it is thin, it prevents definition of the image on the display from being distorted by multiple reflection.

The plate (2), which is fixed to the display (A) surfaces, is manufactured such that it will be in accordance with size and shape of existing liquid crystal displays (A).

The groove (3) included in the inventive heat insulation barrier (1) is created by laser processing such that interconnection of the surfaces will not completely break off, between two surfaces of the plate (2). In a preferred embodiment, the groove (3) created by laser processing is located among all surfaces apart from the edge surfaces of the plate (2). The groove (3) created is configured to prevent convection of heat reaching the display (A) from external factors, and to provide heat insulation. The groove (3) is created on the plate (2) planarly and thus it is ensured that the image is not distorted.

The inventive heat insulation barrier (1) enables heat management by being fixed to the existing displays (A). The heat insulation barrier (1) fixed to the displays (A) can operate at higher and/or lower temperatures in comparison to existing displays (A) without causing any disruption in brightness or image quality of the display (A). In a preferred embodiment, the heat insulation barrier (1) is used on liquid crystal display it in cold stores and glasses with liquid crystal display.

In addition, the present invention also relates to a liquid crystal display (A) comprising the above-mentioned heat insulation barrier (1).

Within these basic concepts; it is possible to develop various embodiments of the inventive heat insulation barrier (1) and a liquid crystal display (A) comprising it (1); the invention cannot be limited to examples disclosed herein and it is essentially according to claims.

1. A heat insulation barrier (1) for providing heat insulation in liquid crystal displays (A) with at least one front surface and one back surface;
characterized by
at least one plate (2) which has two opposite planar surfaces that can be fixed to the front and/or the back surface of the displays (A); and
at least one groove (3) which is located between two surfaces of the plate (2), and created such that interconnection of the surfaces will not completely break off.

2. A heat insulation barrier (1) according to claim 1; characterized by the plate (2) which creates a layer on the surface of the displays (A) of liquid crystal display type, by being fixed to the front surface and/or the back surface of the displays (A) such that no gap will remain between it and the display surface.

3. A heat insulation barrier (1) according to claim 1;
characterized by the plate (2) which is fixed onto the related surface of the display (A) by means of transparent polymer-based materials curing and hardening by heat or UV light.

4. A heat insulation barrier (1) according to claim 1; characterized by the plate (2) which is made of a thin transparent glass material, and configured such that it will have a maximum thickness of 1 mm.

5. A heat insulation barrier (1) according to claim 1; characterized by the plate (2) which is manufactured such that it will be in accordance with size and shape of existing liquid crystal displays (A).

6. A heat insulation barrier (1) according to claim 1; characterized by the groove (3) which is created by laser processing such that interconnection of the surfaces will not completely break off, between two surfaces of the plate (2).

7. A heat insulation barrier (1) according to claim 1; characterized by the groove (3) which is located among all surfaces apart from the edge surfaces of the plate (2).

8. A heat insulation barrier (1) according to claim 1; characterized by the groove (3) which is configured to prevent convection of heat reaching the display (A) from external factors, and to provide heat insulation.

9. A heat insulation barrier (1) according to claim 1; characterized by the groove (3) which is created on the plate (2) planarly.

10. A heat insulation barrier (1) according to claim 1; which is used on liquid crystal display monitors in cold stores and glasses with liquid crystal display.

11. A liquid crystal display (A) comprising a heat insulation barrier (1) according to claim 1.
